(19) United States
(12) Patent Application Publication
(10) Pub. No.: US 2012/0286835 A1
(43) Pub. Date: Nov. 15, 2012

(54) PLL CIRCUIT

(75) Inventors: Yuji Yamada, Osaka (JP); Masayoshi Kinoshita, Osaka (JP); Kazuaki Sogawa, Osaka (JP)

(73) Assignee: Panasonic Corporation, Osaka (JP)

(21) Appl. No.: 13/555,674

(22) Filed: Jul. 23, 2012

Related U.S. Application Data
(63) Continuation of application No. PCT/JP2011/000339, filed on Jan. 24, 2011.

(30) Foreign Application Priority Data
Mar. 4, 2010 (JP) 2010-047343

(51) Int. Cl. H03L 7/08

(52) U.S. Cl. 327/156

(57) ABSTRACT

A PLL circuit includes: a frequency division section; a phase detector configured to detect the phase difference between a reference clock signal and an output signal of the frequency division section; a loop filter configured to filter an output signal of the phase detector and output the result as a digital value; a selector configured to select either the digital value or a fixed value; a digitally controlled oscillator configured to oscillate at a frequency corresponding to the value selected by the selector; and a control section configured to instruct the selector to select the fixed value until receiving a start signal, and after receiving the start signal, instruct the selector to select the digital value, and the frequency division section to start output, at timing of an edge of the reference clock signal.

### CROSS-REFERENCE TO RELATED APPLICATION

This is a continuation of PCT International Application PCT/JP2011/000339 filed on Jan. 24, 2011, which claims priority to Japanese Patent Application No. 2010-047343 filed on Mar. 4, 2010. The disclosures of these applications including the specifications, the drawings, and the claims are hereby incorporated by reference in their entirety.

### BACKGROUND

The present disclosure relates to phase locked loop (PLL) circuits, and more particularly to digital PLL circuits.

A PLL circuit compares the phase of a reference clock signal with the phase of a frequency-divided signal generated by dividing the frequency of the output of an oscillator, and controls the frequency of the oscillator according to the resultant phase difference to output a signal with a desired frequency. As the oscillator, a voltage controlled oscillator (VCO) where the frequency is controlled with an analog voltage and a digitally controlled oscillator (DCO) where the frequency is controlled with a digital value are used. In recent years, with the fabrication process for semiconductor integrated circuits being increasingly miniaturized, the DCO is used in many cases because the frequency thereof is less dependent on the fabrication process. However, the frequency of the VCO or the DCO, whichever is used, is affected by variations in the power supply voltage and temperature of the PLL circuit. As measures against such variations, trimming, etc. is performed in the fabrication process for semiconductor integrated circuits. However, this increases the testing time for semiconductor integrated circuits, etc., causing increase in cost.

Moreover, irrespective of which is used, the VCO or the DCO, the PLL circuit has similar band limitation imposed by a loop filter. Therefore, use of a reference clock signal having a low frequency will increase the pull-in time. When a PLL circuit receiving a low-frequency reference clock signal is used in a semiconductor integrated circuit for a communication system and a digital home appliance, the performance of an application operating in response to the output of the PLL circuit will be degraded because the pull-in time of the PLL circuit affects the startup time of the system. While the pull-in time of the PLL circuit is about 10 ms when the frequency of the reference clock signal is 10 kHz, for example, it is about 10 μs when it is 10 MHz, for example. The difference between the above pull-in times, which is about 1000-fold, will appear in the specification of the application as it is. Therefore, shortening the pull-in time of the PLL circuit has great significance.

Under the above circumstances, conventionally, after the PLL circuit has once completed its pull-in operation, it keeps supplying the reference clock signal to two inputs of the phase comparator to maintain the pulled-in state, thereby creating a quasi pulled-in state. When being started again, the PLL circuit can restart from the quasi pulled-in state, whereby high-speed pull-in operation is achieved (see Japanese Patent Publication No. H08-223038, for example).

### SUMMARY

The conventional PLL circuit must have once performed pull-in operation; it is only at the second or subsequent time that the PLL circuit can achieve high-speed pull-in operation. However, in the present systems for which high-speed startup is asked, shortening the first pull-in time is important. By shortening the first pull-in time, the startup time of the entire system can be shortened, permitting improvement in the performance of an application.

In an example PLL circuit using a digitally controlled oscillator, the first pull-in operation after startup can be performed at high speed.

According to an embodiment of the present disclosure, the PLL circuit includes: a frequency division section configured to divide the output of the PLL circuit; a phase detector configured to detect a phase difference between a reference clock signal and an output signal of the frequency division section; a loop filter configured to filter an output signal of the phase detector and output the filtering result as a digital value; a selector configured to select either the digital value or a fixed value; a digitally controlled oscillator configured to oscillate at a frequency corresponding to the value selected by the selector; and a control section configured to instruct the selector to select the fixed value until receiving a start signal, and after receiving the start signal, instruct the selector to select the digital value, and the frequency division section to start output, at timing of an edge of the reference clock signal.

With the above configuration, a fixed value selected by the selector is supplied to the digitally controlled oscillator until receipt of the start signal. Therefore, by setting a fixed value corresponding to a desired frequency in a fixed value setting section, the digitally controlled oscillator is oscillating at the desired frequency at the time of receipt of the start signal. Then, at the timing of an edge of the reference clock signal after the receipt of the start signal, the digital value output from the loop filter is supplied to the digitally controlled oscillator via the selector, thereby forming a loop, and also the frequency division section starts its output, eliminating the phase difference in the phase detector. Thus, the PLL circuit immediately enters its locked state.

The PLL circuit described above may further include a reference circuit configured to output one of a plurality of fixed values to the selector as the fixed value. With this configuration, the fixed value can be easily changed according to a system using the output of the PLL circuit. Also, the PLL circuit may further include: a temperature detector configured to detect the temperature of the PLL circuit; and a voltage detector configured to detect the power supply voltage of the PLL circuit. The reference circuit may output one of the plurality of fixed values to the selector based on the temperature and the power supply voltage. With this configuration, the fixed value can be set to be adaptive to variations in the temperature and power supply voltage of the PLL circuit.

Preferably, the frequency division section may include a plurality of frequency dividers connected in series. With this configuration, the signals output from the frequency dividers, which have different frequencies, can be used for various circuits.

### BRIEF DESCRIPTION OF THE DRAWINGS

FIG. 1 is a block diagram of a PLL circuit of an embodiment of the present disclosure.

FIG. 2 is a block diagram showing an example configuration of a frequency division section in FIG. 1.

FIG. 3 is a block diagram showing an example configuration of a fixed value setting section in FIG. 1.

FIG. 4 is a block diagram showing another example configuration of the fixed value setting section in FIG. 1.

FIG. 5 is a block diagram showing an example configuration of a control section in

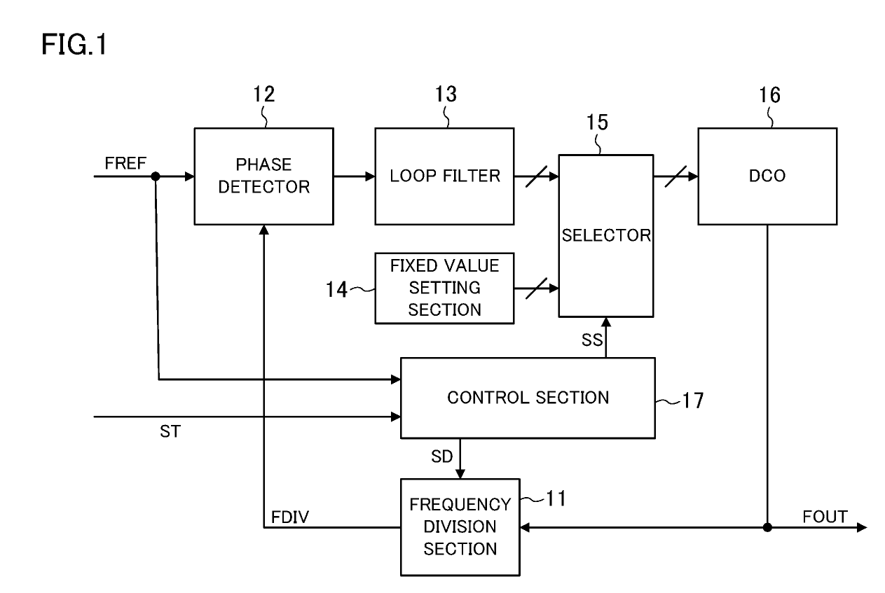

FIG. 1.

FIG. 6 is a timing chart of the PLL circuit of this embodiment.

### DETAILED DESCRIPTION

FIG. 1 is a block diagram of a PLL circuit of an embodiment of the present disclosure. The PLL circuit outputs a signal FOUT that is in phase with an input reference clock signal FREF and has a frequency obtained by multiplying the frequency of the reference clock signal FREF.

First, the configuration of the PLL circuit will be summarized. A phase detector 12 detects the phase difference between the reference clock signal FREF and a frequency-divided signal FDIV generated by dividing the frequency of the signal FOUT, and outputs a signal corresponding to the phase difference to a loop filter 13. The loop filter 13 filters the output signal of the phase detector 12 and outputs the result to a selector 15 as a digital value. The selector 15 selects either the output of the loop filter 13 or the output of a fixed value setting section 14 according to a control signal SS output from a control section 17, and outputs the selected one to a DCO 16. Receiving the output of the selector 15, the DCO 16 outputs the signal FOUT having a frequency corresponding to the output value of the selector 15. The frequency division section 11 divides the frequency of the signal FOUT in response to a control signal SD output from the control section 17, and feeds back the resultant frequency-divided signal FDIV to the phase detector 12. The fixed value setting section 14, which holds a fixed value (digital value) to be set for the DCO 16, outputs the fixed value to the selector 15. The selector 15 selects the output of the fixed value setting section 14 when the control signal SS is low, or selects the output of the loop filter 13 when it is high. The control section 17 controls the frequency division section 11 and the selector 15 in response to the reference clock signal FREF and a start signal ST.

Next, specific examples of the frequency division section 11, the fixed value setting section 14, and the control section 17 will be described in detail.

The frequency division section 11 can be constituted by a single frequency divider that divides the frequency of the signal FOUT by N (N is a positive integer). For example, the frequency division section 11 can be configured to start counting pulses of the signal FOUT when the control signal SD goes high, and outputs the high-level frequency-divided signal FDIV once the count reaches N.

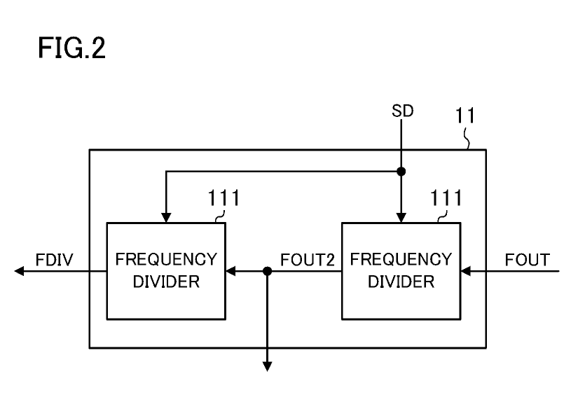

Alternatively, the frequency division section 11 may be constituted by a plurality of frequency dividers connected in series. FIG. 2 shows an example of the frequency division section 11 constituted by two frequency dividers 111. In the frequency division section 11 of FIG. 2, the output of the first-stage frequency divider 111 that receives the signal FOUT is input into the second-stage frequency divider 111. The first-stage and second-stage frequency dividers 111 start their frequency division operation when the control signal SD goes high, and respectively output a frequency-divided signal FOUT2 and the frequency-divided signal FDIV. The frequency-divided signal FOUT2 can be used as an input clock signal for another circuit. In such a circuit, therefore, it will be unnecessary to provide a circuit for generating an input clock signal.

The divisors set by the frequency dividers 111 are arbitrary, and the frequency dividers 111 may be controlled individually with the control signal SD. The number of frequency dividers 111 may be three or more.

Referring back to FIG. 1, the fixed value setting section 14 holds a digital value for setting the frequency of the signal FOUT. The fixed value setting section 14 may hold one digital value, or may hold a plurality of digital values and select one of the plurality of digital values to be output to the selector 15.

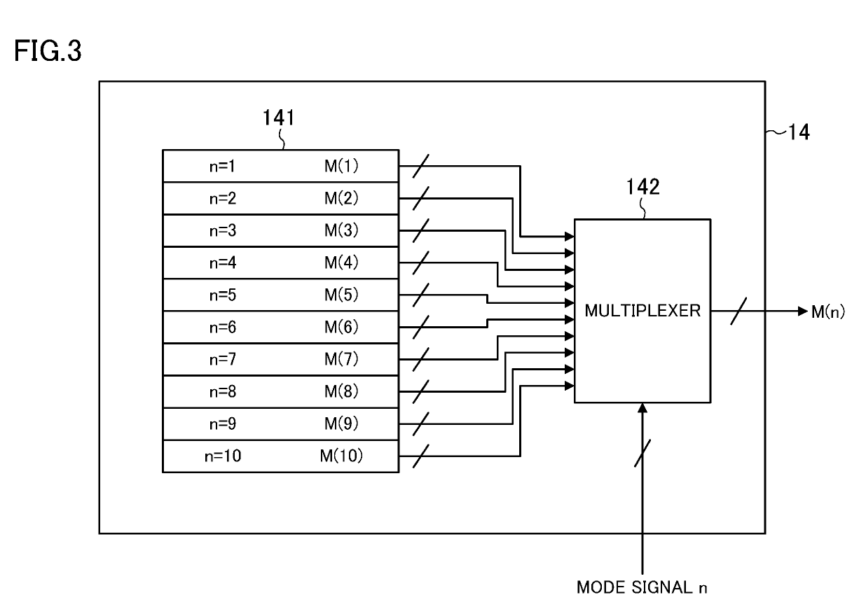

FIG. 3 shows an example configuration of the type of the fixed value setting section 14 that outputs one of a plurality of digital values. The fixed value setting section 14 may be constituted by a table 141 that holds the plurality of digital values and a multiplexer 142 that acquires a digital value corresponding to a mode signal n from the table 141. The mode signal as used herein refers to a signal representing the operation mode, etc. of an application that operates in response to the signal FOUT. For example, in a digital TV set including the PLL circuit of this embodiment, the mode signal is a signal indicating “wide,” “normal,” etc. as the screen mode of the digital TV set.

In the table 141, ten different digital values M(1) to M(10) are stored in association with the values of n. The multiplexer 142, receiving the mode signal n, outputs the digital value M(n) corresponding to the value of n. For example, when the value of n is “2,” the digital value M(2) is output. In this way, the fixed value setting section 14 can output a digital value corresponding to the mode signal. In other words, the PLL circuit can output the signal FOUT having a frequency corresponding to the operation mode of an application that operates in response to the signal FOUT.

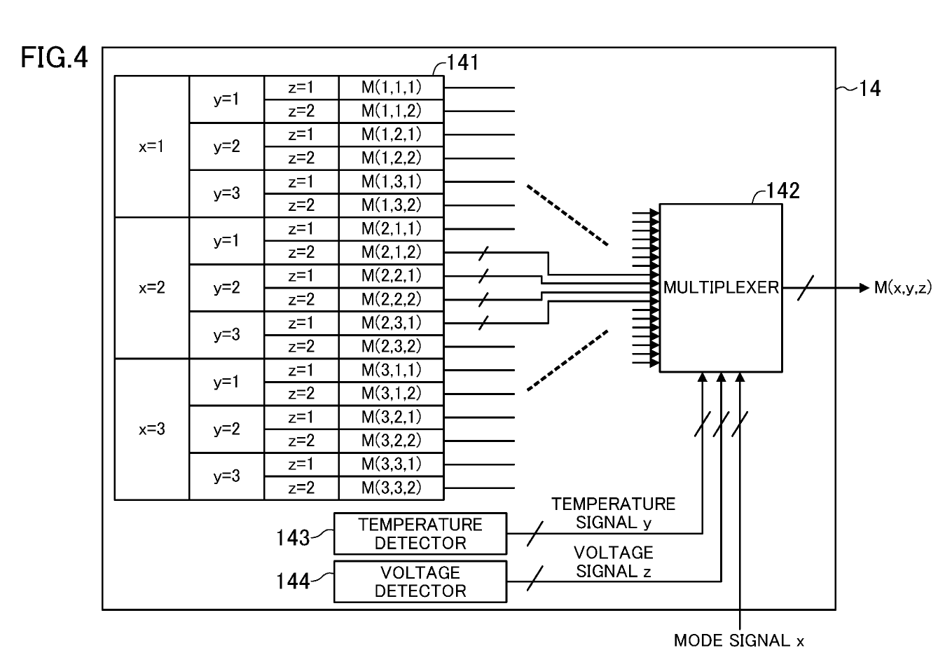

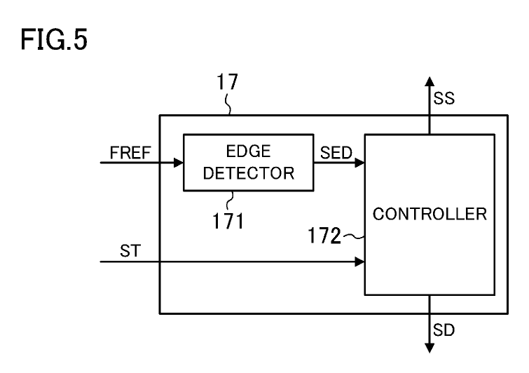

FIG. 4 shows another example configuration of the type of the fixed value setting section 14 that outputs one of a plurality of digital values. The fixed value setting section 14 of FIG. 4 includes a table 141, a multiplexer 142, a temperature detector 143 for detecting the temperature of the PLL circuit, and a voltage detector 144 for detecting the power supply voltage of the PLL circuit. The temperature of the PLL circuit may be the temperature of the DCO 16, for example. The power supply voltage of the PLL circuit may be the power supply voltage of the DCO 16, for example. The temperature detector 143 outputs a temperature signal y indicating to which one, among a plurality of predetermined temperature ranges, the detected temperature belongs. The voltage detector 144 outputs a voltage signal z indicating to which one, among a plurality of predetermined voltage ranges, the detected voltage belongs. For example, the mode signal x and the temperature signal y take three values, and the voltage signal z takes two values.

In the table 141, 18 different digital values M(1,1,1) to M(3,3,2) are stored in association with the combinations of the values of x, y, and z. The multiplexer 142, receiving the mode signal x, the temperature signal y, and the voltage signal z, outputs the digital value M(x,y,z) corresponding to a combination of the values of these signals. For example, when the value of x is “2,” the value of y is “3,” and the value of z is “1,” the digital value M(2,3,1) is output.

In general, the oscillating frequency of the DCO varies with the temperature and the power supply voltage. However, with the configuration of FIG. 4, in which the digital value corresponding to the temperature and power supply voltage of the PPL circuit is output, the DCO 16 can immediately output the signal FOUT having a desired frequency specified by the mode signal even under any of various temperature and voltage conditions.

In the fixed value setting section 14 of FIG. 4, the mode signal x may be omitted. In this case, with the value of x being unnecessary in the table 141, the multiplexer 142 can output a digital value M(y,z) corresponding to the value of the temperature signal y and the value of the voltage signal z.

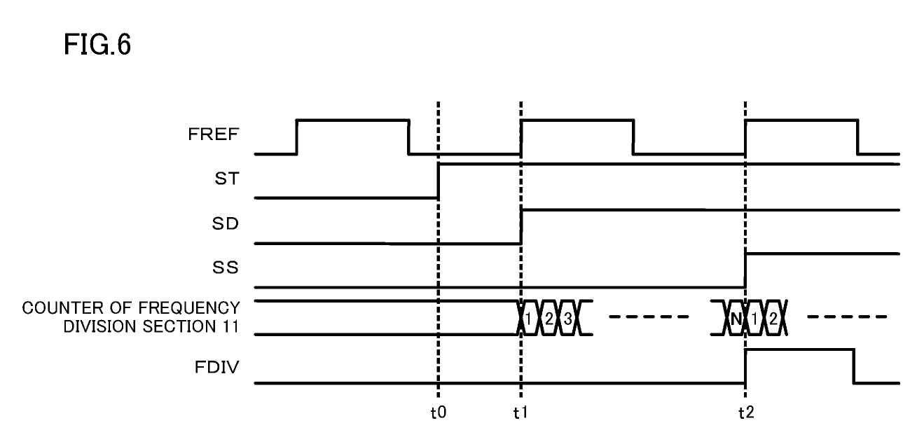

Referring back to FIG. 1 again, the control section 17 receives the reference clock signal FREF and the start signal ST, and outputs the control signal SS to the selector 15 and the control signal SD to the frequency division section 11. FIG. 5 shows an example configuration of the control section 17. The control section 17 can be constituted by an edge detector 171 that detects a rising edge, for example, of the reference clock signal FREF and outputs an edge detection signal SED and a controller 172 that receives the edge detection signal SED and the start signal ST and outputs the control signals SS and SD. The start signal ST is a signal output after the lapse of the time required from the start of the operation of the DCO 16 until the DCO 16 can finally oscillate at a desired frequency. Otherwise, the start signal ST may be a signal indicating that an external system that is to operate in response to the signal FOUT has become operable. The controller 172 keeps the control signals SD and SS at their low levels during the time when the start signal ST is low. After the start signal ST goes high, the controller 172 outputs the high-level control signals SD and SS upon receipt of the edge detection signal SED. The controller 172 may output the high-level control signal SS after outputting the high-level control signal SD.

Next, the operation of the PLL circuit of this embodiment will be described with reference to FIG. 6. Until time t0, the operation of an external system, for example, is not yet prepared, and the start signal remains low. Therefore, even if the edge detector 171 detects a rising edge of the reference clock signal FREF and the controller 172 receives the edge detection signal SED before time t0, the control signal SD and the control signal SS remain low. With the control signal SS being low, the selector 15 selects the fixed value output from the fixed value setting section 14. The DCO 16 then outputs the signal FOUT of which the frequency is determined by the selected fixed value. Also, with the control signal SD being low, the frequency division section 11 does not operate, and thus the frequency-divided signal FDIV remains low.

At time t0, at which the external system becomes operable, the start signal ST goes high. Thereafter, when detecting a rising edge of the reference clock signal FREF at time t1, the edge detector 171 outputs the edge detection signal SED. In response to this signal, the controller 172 outputs the high-level control signal SD, causing the frequency division section 11 to start operation. Thus, a counter in the frequency division section 11 counts pulses of the signal FOUT.

Once the count reaches N at time t2, the frequency division section 11 outputs the high-level frequency-divided signal FDIV, where N is the divisor of the frequency division section 11. Also, the controller 172 makes the control signal SS go high. The selector 15 then selects the digital value output from the loop filter 13. Thus, the PLL circuit is put in the locked state.

As described above, in this embodiment, the signal FOUT that has a desired frequency and is in phase with the reference clock signal FREF can be obtained in the time equal to the sum of the time from the input of the start signal ST until the timing of the rising edge of the reference clock signal FREF and one period of the reference clock signal FREF.

The DCO 16 may just be an oscillator performing the frequency control with a digital value. For example, an analog PLL circuit may be used for the DCO. In this case, the output of the selector 15 is input into a frequency divider placed inside the analog PLL circuit. In other words, the divisor of the frequency divider in the analog PLL circuit is set from the digital value output from the selector 15. This makes it possible to control the oscillating frequency of the analog PLL circuit with the digital value output from the selector 15. When an analog PLL circuit, for example, is used for the DCO 16, the digital value to be held in the fixed value setting section 14 can be determined according to the ratio of the frequency of the reference clock signal input into the analog PLL circuit to the frequency of the signal FOUT.

The frequency division section 11 may count pulses of the signal FOUT in advance, and start output of the frequency-divided signal FDIV, and also reset the count to restart counting, when the control signal SD goes high. In this case, the control section 17 may output the high-level control signal SD after outputting the high-level control signal SS. The relationships between the operations of the components and the logical levels of the signals are not limited to those described above. For example, the frequency division section 11 may not operate when the control signal SD is high, and start operating when the control signal SD goes low.

What is claimed is:

1. A PLL circuit, comprising:
a frequency division section configured to divide the output of the PLL circuit;
a phase detector configured to detect a phase difference between a reference clock signal and an output signal of the frequency division section;
a loop filter configured to filter an output signal of the phase detector and output the filtering result as a digital value;
a selector configured to select either the digital value or a fixed value;
a digitally controlled oscillator configured to oscillate at a frequency corresponding to the value selected by the selector; and
a control section configured to instruct the selector to select the fixed value until receiving a start signal, and after receiving the start signal, instruct the selector to select the digital value, and the frequency division section to start output, at timing of an edge of the reference clock signal.

2. The PLL circuit of claim 1, wherein
the control section instructs the frequency division section to start output after instructing the selector to select the digital value.

3. The PLL circuit of claim 1, further comprising:
a reference circuit configured to output one of a plurality of fixed values to the selector as the fixed value.

4. The PLL circuit of claim 3, further comprising:
a temperature detector configured to detect the temperature of the PLL circuit; and
a voltage detector configured to detect the power supply voltage of the PLL circuit, wherein
the reference circuit outputs one of the plurality of fixed values to the selector based on the temperature and the power supply voltage.

5. The PLL circuit of claim 1, wherein
the frequency division section includes a plurality of frequency dividers connected in series.

6. The PLL circuit of claim 1, wherein
the start signal is a signal indicating that a predetermined time has passed from start of the operation of the digitally controlled oscillator.

7. The PLL circuit of claim 1, wherein
the start signal is a signal indicating that an external system has become operable based on the output of the PLL circuit.
